(19) United States
(12) Patent Application Publication
(10) Pub. No.: US 2024/0170293 A1
(43) Pub. Date: May 23, 2024

(54) Silicon Etching Solution, Method for Treating Substrate, and Method for Manufacturing Silicon Device

(71) Applicant: Tokuyama Corporation, Yamaguchi (JP)

(72) Inventors: Tatsuya Hitomi, Yamaguchi (JP); Yoshiki Seike, Yamaguchi (JP); Kohsuke Noro, Yamaguchi (JP)

(73) Assignee: Tokuyama Corporation, Yamaguchi (JP)

(21) Appl. No.: 18/515,403

(22) Filed: Nov. 21, 2023

(30) Foreign Application Priority Data
Nov. 22, 2022 (JP) 2022-186882
Nov. 17, 2023 (JP) 2023-195607

(51) Int. Cl. H01L 21/306; H01L 21/3213

(52) U.S. Cl. CPC H01L 21/30608; H01L 21/32134

(57) ABSTRACT

An etching solution has a high etching selectivity of silicon with respect to silicon-germanium and having high stability over time at a treating temperature in surface processing in manufacturing various semiconductor devices, particularly in various silicon composite semiconductor devices containing silicon-germanium. The silicon etching solution contains a compound having at least one carboxy group and having all pKa of 3.5 or more and 13 or less, or a salt thereof; an organic alkali; and water.

### BACKGROUND OF THE INVENTION

### Field of the Invention

The present invention relates to a silicon etching solution. More specifically, the present invention relates to a silicon etching solution (hereinafter, also referred to as an etching solution) used for etching silicon (Si) to perform fine processing or the like in manufacturing a semiconductor device. In particular, the present invention relates to an etching solution useful for selectively etching silicon without etching silicon-germanium. The present invention also relates to a method for treating a substrate using the etching solution. Examples of the substrate include a semiconductor wafer or a silicon substrate. The present invention further relates to a method for manufacturing a silicon device using the etching solution.

### Description of the Related Art

In a process for manufacturing a semiconductor device, silicon etching is used in various steps. In recent years, the silicon etching has been applied to producing a structure called a fin field-effect transistor (Fin-FET) or gate all around (GAA), and is essential for stacking of memory cells or three-dimensionalization of a logic device. In a silicon etching technique used here, due to densification of a device, a stricter requirement is imposed on smoothness of a wafer surface after etching, an etching accuracy, an etching selectivity to other materials, and the like. In addition, the etching technique is also applied to a process such as silicon wafer thinning. Such various semiconductor devices are required to be highly integrated, miniaturized, highly sensitive, and highly functional depending on applications thereof, and in order to satisfy these requirements, the silicon etching is considered important as a fine processing technique in manufacturing these semiconductor devices.

On the other hand, various silicon etching solutions are proposed and are actually used. Among them, it is widely known that a silicon etching solution made of an alkaline aqueous solution exhibits crystal plane anisotropy in etching of crystalline silicon.

As such a silicon etching solution made of an alkaline aqueous solution, there has been proposed a silicon etching solution to which various additives are added in addition to an alkaline compound and water in order to improve various characteristics or to exhibit new characteristics. One of such additives is a reducing sugar (see, for example, Patent Document 1). In this technique, the reducing sugar improves an etching rate of silicon and is used as an anticorrosive that prevents etching of aluminum or an aluminum alloy. It is said that a part of the reducing sugar forms an aldehyde structure in the aqueous solution, and this aldehyde exhibits a reducing property, and thus reduces an influence of dissolved oxygen to exhibit the above effect.

Patent Document 2 also proposes adding an aldehyde to an alkaline silicon etching solution for a purpose of trapping hydrogen generated when silicon is dissolved. Patent Document 3 discloses a polishing composition containing a quaternary ammonium salt, a carboxylic acid, hydrogen peroxide, water, and an abrasive. Patent Document 4 discloses a semiconductor cleaning composition containing a quaternary ammonium compound, a carboxylic acid, hydrogen peroxide, and a surfactant. Patent Document 5 discloses a polishing composition containing an abrasive grain, an inorganic salt and a polishing accelerator having an acid group, and an acid or alkali as a pH adjuster.

On the other hand, in recent years, various methods for producing a silicon composite semiconductor device using silicon-germanium are also increased, and may be used for manufacturing nanowires in the above GAA structure. For example, a silicon layer and a silicon-germanium layer are alternately stacked by epitaxial growth using a specific substrate as a base, and then etching is performed for the silicon layer only as a sacrificial layer, whereby the silicon-germanium layer can be left as a channel layer. At this time, etching that can uniformly remove only silicon without dissolving silicon-germanium, a silicon oxide film, and a silicon nitride film is important.

Further, in a memory application, a memory cell having a 3D NAND structure or the like becomes multilayered, and etching of silicon may be used in a process of forming such a structure. For example, polysilicon and a silicon oxide film are alternately stacked, a hole that penetrates layers is formed, and then polysilicon exposed on a side wall of the hole is uniformly etched to form a groove. At this time, etching that can uniformly remove only silicon without dissolving a silicon oxide film and a silicon nitride film is also important.

### PRIOR ART DOCUMENTS

### Patent Documents

Patent Document 1: Japanese Patent Laid-Open No. 2006-054363
Patent Document 2: Japanese Patent Laid-Open No. H10-46369
Patent Document 3: Japanese Patent Laid-Open No. 2002-231666
Patent Document 4: Japanese Patent Laid-Open No. 2014-103349
Patent Document 5: Japanese Patent Laid-Open No. 2021-150515

### SUMMARY OF THE INVENTION

### Problem to be Solved by the Invention

As described above, adding the reducing sugar to the silicon etching solution made of the alkaline aqueous solution has many advantages. As a result of studies, the present inventors have found that a pH of the alkaline silicon etching solution to which the reducing sugar is added rapidly decreases during storage, and thus an etching rate of silicon also decreases. Generally, it is assumed that the silicon etching solution is repeatedly used at a treating temperature. Therefore, when the etching rate changes over time, there is a large problem in applications such as manufacturing of a semiconductor requiring a strict etching depth (thickness). In addition, the polishing compositions or the cleaning compositions described in Patent Document 3-5 are not intended to be applied to silicon etching.

### SUMMARY OF THE INVENTION

Therefore, an object of the present invention is to provide an etching solution having a high etching selectivity of silicon with respect to silicon-germanium and having high stability over time at a treating temperature in surface processing in manufacturing various semiconductor devices, particularly in various silicon composite semiconductor devices containing silicon-germanium.

The present inventors have conducted intensive studies in view of the above problems, and have made a hypothesis that decomposition of a reducing sugar under an alkaline condition causes a decrease in pH and that a decomposition product contributes to prevention of etching of silicon-germanium. As a result of a study focusing on the decomposition product, it has been found that a compound having at least one carboxy group and all acid dissociation constants (hereinafter referred to as pKa) of 3.5 or more and 13 or less, or a salt thereof, contributes to the prevention of the etching of silicon-germanium, thereby completing the present invention.

That is, the present invention includes the following gist.

(1) A silicon etching solution containing:
an organic alkali;
water; and
a compound having at least one carboxy group and having all pKa of 3.5 or more and 13 or less, or a salt thereof.

(2) The silicon etching solution according to (1), in which the compound has an HLB value of 22.0 or more and 25.5 or less.

(3) The silicon etching solution according to (1), in which the compound is a compound not containing an amine moiety.

(4) The silicon etching solution according to (1), in which the compound is one or more compounds selected from the group consisting of propanoic acid, butanoic acid, pentanoic acid, hexanoic acid, heptanoic acid, octanoic acid, isopropanoic acid, isobutanoic acid, isopentanoic acid, isohexanoic acid, isoheptanoic acid, isooctanoic acid, 2-cyclobutylacetic acid, cyclopentanecarboxylic acid, cyclohexanecarboxylic acid, succinic acid, glutaric acid, adipic acid, pimelic acid, suberic acid, azelaic acid, sebacic acid, tridecanedioic acid, methylsuccinic acid, tetramethylsuccinic acid, benzoic acid, terephthalic acid, and gluconic acid.

(5) The silicon etching solution according to (1), in which the organic alkali is a quaternary ammonium hydroxide.

(6) The silicon etching solution according to (5), in which the quaternary ammonium hydroxide is a quaternary ammonium hydroxide having 8 or less carbon atoms.

(7) A method for treating a silicon wafer or a substrate, including: selectively etching silicon with respect to silicon-germanium in a silicon wafer including a silicon-germanium film, or selectively etching at least one selected from the group consisting of a single crystal silicon film, a polysilicon film, and an amorphous silicon film with respect to silicon-germanium in a substrate including a silicon-germanium film, by using the silicon etching solution according to any one of (1) to (6).

(8) A method for manufacturing a silicon device, including: a step of selectively etching silicon with respect to silicon-germanium in a silicon wafer including a silicon-germanium film, or a step of selectively etching at least one selected from the group consisting of a single crystal silicon film, a polysilicon film, and an amorphous silicon film with respect to silicon-germanium in a substrate including a silicon-germanium film, by using the silicon etching solution according to any one of (1) to (6).

By using the etching solution of the present invention, a treatment with a high etching selectivity of silicon with respect to silicon-germanium can be performed. In addition, the etching solution of the present invention has good stability over time during continuous use, as compared with an etching solution made of an alkaline aqueous solution to which an aldehyde compound such as a reducing sugar is added. Therefore, by using the etching solution of the present invention, it is possible to manufacture a semiconductor device or the like with high productivity.

### DETAILED DESCRIPTION OF THE PREFERRED EMBODIMENTS

Hereinafter, an embodiment of the present invention will be described in detail, but the present invention is not limited to these contents unless the gist thereof is exceeded. In addition, the present invention can be freely modified and implemented within a scope without departing from the gist thereof.

In the present specification, a numerical range expressed using “to” means a range including numerical values described before and after “to” as a lower limit value and an upper limit value, and “A to B” means A or more and B or less.

### 1. Etching Solution

A silicon etching solution of the present invention (hereinafter referred to as an “etching solution of the present invention”) is used for etching silicon (crystalline silicon, polysilicon, and amorphous silicon) during manufacturing of a semiconductor chip or the like. Etching of silicon can be performed under an acid condition or under an alkaline condition, but the etching solution of the present invention is an alkaline aqueous solution and is used for etching under the alkaline condition.

In the above manufacturing of a semiconductor chip, when a treatment solution such as an etching solution contains a metal, the metal often has an adverse influence on an object to be treated (not limited to a silicon plane to be etched).

Therefore, it is necessary that the etching solution of the present invention does not contain a metal. More specifically, it is essential that the etching solution does not contain the metal at least at a concentration exceeding an impurity level. Preferably, each of Ag, Al, Ba, Ca, Cd, Co, Cr, Cu, Fe, K, Li, Mg, Mn, Na, Ni, Pb, and Zn has a content of 1 ppmw or less, and more preferably, each of the above metals has a content of 1 ppbw or less. Each of the metals listed herein is a metal that is expected to influence quality in a chemical solution used for manufacturing a semiconductor.

Further, among the above metals, any one metal selected from iron, copper, manganese, chromium, and zinc is preferably 0.01 ppt or more and 1 ppb or less, more preferably 0.01 ppt or more and 0.5 ppb or less, even more preferably 0.01 ppt or more and 0.2 ppb or less, and most preferably 0.01 ppt or more and 0.1 ppb or less on a weight basis. The etching solution of the present invention may contain an ionic metal or a nonionic metal (particulate metal) as a metal. A total concentration of the ionic metal and the nonionic metal is preferably in the above range.

An alkaline source in the etching solution of the present invention is an organic alkali.

Examples of the organic alkali include an onium hydroxide. Examples of the onium hydroxide include a quaternary ammonium hydroxide and various amines. Such an organic alkali may be selected and used according to the object and the purpose of the silicon etching in accordance with known characteristics thereof. Among them, quaternary ammonium hydroxides and tertiary amines are more preferable because stability of the silicon etching solution over time is further improved, and quaternary ammonium hydroxides are particularly preferable because the stability of the silicon etching solution over time is remarkable.

Specific examples of the quaternary ammonium hydroxide include tetramethylammonium hydroxide, ethyltrimethylammonium hydroxide, propyltrimethylammonium hydroxide, butyltrimethylammonium hydroxide, tetraethylammonium hydroxide, tetrapropylammonium hydroxide, tetrabutylammonium hydroxide, trimethyl-2-hydroxyethylammonium hydroxide, dimethylbis(2-hydroxyethyl)ammonium hydroxide or methyltris(2-hydroxyethyl)ammonium hydroxide, phenyltrimethylammonium hydroxide, and benzyltrimethylammonium hydroxide.

The smaller a cation size is, the more easily the alkali is diffused, or the lower the hydrophobicity is, and the less difficult the prevention of etching by adsorption to a silicon surface is. Therefore, from a viewpoint of a tendency of increasing an etching rate and productivity, among them, an organic alkali, particularly, a quaternary ammonium hydroxide having a total number of carbon atoms of 8 or less is preferable, an organic alkali, particularly, a quaternary ammonium hydroxide having a total number of carbon atoms of 7 or less is more preferable. Among them, tetramethylammonium hydroxide, ethyltrimethylammonium hydroxide, butyltrimethylammonium hydroxide, or propyltrimethylammonium hydroxide is particularly preferable.

As the various amines, primary amines, secondary amines, or tertiary amines can be used, and as described above, tertiary amines are preferable because deterioration of the etching solution is less likely to occur.

As the primary amines or the secondary amines, for example, one or more selected from the group consisting of ethylenediamine, 1,3-diaminopropane, 1,4-diaminobutane, 1,5-diaminopentane, 1,6-diaminohexane, 1,7-diaminoheptane, 1,8-diaminooctane, 1,1,3,3-tetramethylguanidine, diethylenetriamine, dipropylenetriamine, bis(hexamethylene)triamine, N,N,N-trimethyldiethylenetriamine, N,N-bis(3-aminopropyl)ethylenediamine, 2-(2-aminoethoxy)ethanol, 2-amino-2-methyl-1-propanol, 4-amino-1-butanol, 5-amino-1-pentanol, 6-amino-1-hexanol, N-(2-aminoethyl)propanolamine, N-(2-hydroxypropyl)ethylenediamine, azetidine, pyrrolidine, piperidine, hexamethyleneimine, pentamethyleneimine, and octamethyleneimine can be used.

Specifically, examples of the tertiary amines include one or more selected from the group consisting of 2-(dimethylamino)ethanol, 3-(dimethylamino)-1-propanol, 4-dimethylamino-1-butanol, 2-(diethylamino)ethanol, triethylamine, methylpyrrolidine, methylpiperidine, 1,8-diazabicyclo[5.4.0]undec-7-ene, and 1,5-diazabicyclo[4.3.0]non-5-ene. More preferable examples thereof include one or more selected from the group consisting of ethylenediamine, 1,3-diaminopropane, 1,4-diaminobutane, 1,5-diaminopentane, 1,6-diaminohexane, 1,1,3,3-tetramethylguanidine, diethylenetriamine, dipropylenetriamine, bis(hexamethylene)triamine, 2-(2-aminoethoxy)ethanol, 2-amino-2-methyl-1-propanol, 4-amino-1-butanol, 5-amino-1-pentanol, 6-amino-1-hexanol, N-(2-aminoethyl)propanolamine, pyrrolidine, piperidine, hexamethyleneimine, and pentamethyleneimine. Even more preferable examples thereof include one or more selected from the group consisting of ethylenediamine, 1,3-diaminopropane, 1,4-diaminobutane, 1,5-diaminopentane, 1,6-diaminohexane, 1,1,3,3-tetramethylguanidine, diethylenetriamine, dipropylenetriamine, bis(hexamethylene)triamine, 2-(2-aminoethoxy)ethanol, 2-amino-2-methyl-1-propanol, pyrrolidine, and piperidine.

In the etching solution of the present invention, regarding the organic alkali used as the alkaline source, one type may be used alone, or a plurality of different types thereof may be mixed and used.

The etching solution of the present invention may contain ammonia in addition to the above organic alkali. However, the alkaline source is particularly preferably only an organic alkali because the ammonia may volatilize outside the system in a form of free ammonia when the ammonia is used as the alkaline source.

For both silicon and silicon-germanium etching, the etching rate tends to be larger as an alkali concentration is higher (therefore, an alkaline property is higher), so that a selectivity of the etching of silicon with respect to the etching of silicon-germanium has a small dependence on a pH within a range in which the etching of silicon proceeds. Therefore, a pH of the etching solution of the present invention may be appropriately adjusted to achieve a desired silicon etching rate or silicon-germanium etching rate. That is, when it is desired to perform etching at a high etching rate in view of the productivity, the pH of the etching solution may be adjusted to be high, and when it is desired to perform etching at a low etching rate in order to perform fine processing or the like in view of handleability rather than the productivity, the pH of the etching solution may be adjusted to be low. From the viewpoint of the productivity, the etching solution of the present invention has a pH of 10.0 or more, more preferably a pH of 11.0 or more, and particularly preferably a pH of 12.0 or more. On the other hand, the stronger the alkaline property is, the higher the risk of occurrence of leakage or the like is, and a component to be blended for making the alkaline liquid tend to be highly harmful and is also relatively expensive. From such viewpoints, the pH may be 14.0 or less, or may be 13.7 or less. The pH refers to a value measured at 25° C. by a glass electrode method.

The most important feature of the etching solution of the present invention is that the solution contains a compound having at least one carboxy group and having all pKa of 3.5 or more and 13 or less or a salt thereof. The carboxy group is —COOH, the compound having the carboxy group is represented by R—COOH, and the salt thereof is represented by R—COOX (X is, for example, ammonium or tetramethylammonium). Such a compound and a salt thereof are generally dissociated in an alkaline solution and present as R—COO⁻, but also present as R—COOH in a free state (non-dissociation state) at an abundance ratio determined by pKa of a conjugate acid of R—COO⁻ and the pH of the solution. Hereinafter, “a compound having at least one carboxy group and having all pKa of 3.5 or more and 13 or less or a salt thereof” may be simply referred to as a “carboxy group-containing compound”. The pKa of the conjugate acid of the carboxylate anion (R—COO⁻), which is in a dissociated state of the compound having at least one carboxy group and having all pKa of 3.5 or more and 13 or less or a salt thereof has the same meanings as the pKa of the compound having at least one carboxy group and having all pKa of 3.5 or more and 13 or less. Hereinafter, “when the carboxy group-containing compound is a salt, the pKa of the conjugate acid of the carboxylate anion in which the salt is dissociated” may be simply referred to as “the pKa of the carboxy group-containing compound”. In addition, “all pKa” is referred in the present invention includes the case where the number of pKa of the carboxy group-containing compound is one (only first dissociation). By containing the carboxy group-containing compound, the etching rate of silicon-germanium is greatly reduced as compared with the etching rate of silicon and the selectivity of the etching of silicon with respect to the etching of silicon-germanium is improved, compared with the etching solution containing no carboxy group-containing compound.

When the pKa of the carboxy group-containing compound contained in the etching solution is more than 13, solubility may decrease in the etching solution which is an alkaline aqueous solution, so that the pKa of the carboxy group-containing compound is preferably 3.5 or more and 13 or less, more preferably 3.5 or more and 11 or less, even more preferably 3.5 or more and 10 or less, and particularly preferably 3.5 or more and 8 or less.

On the other hand, when any of the pKa of the carboxy group-containing compound is less than 3.5, that is, when the first dissociation pKa is less than 3.5 even when a second dissociation or a third dissociation pKa is 3.5 or more and 13 or less, an effect of improving the selectivity of the etching of silicon with respect to the etching of silicon-germanium is reduced.

A reason for this is not clear, but is presumed as follows. That is, it is known that a surface charge of a silicon surface is generally negative in an alkaline solution, and it is considered that a silicon-germanium surface is the same. Therefore, it is considered that, in the alkaline solution, an anion is less likely to approach the silicon-germanium surface by static repulsion. It is presumed that when the pKa of the carboxy group-containing compound is 3.5 or more, adsorption of a small amount of carboxy group in a non-dissociation state to a hydroxy group on the silicon-germanium surface contributes to the prevention of the etching of silicon-germanium. On the other hand, when the carboxy group-containing compound further has other acidic groups (a carboxy group, a sulfonic acid group, a phosphoric acid group, or a phosphonic acid group) in addition to one carboxy group, and pKa of a compound caused by dissociation of the other acidic groups is less than 3.5, even when the one carboxy group is in a non-dissociation state, a probability that the other acidic groups (a carboxy group, a sulfonic acid group, a phosphoric acid group, or a phosphonic acid group) are in a dissociation state (anion) becomes extremely high. Therefore, it is presumed that, as a result, the anion is less likely to approach the silicon-germanium surface by static repulsion, and an effect of preventing the etching of silicon-germanium is reduced. The carboxy group-containing compound having a carboxy group as the other acidic groups means a compound having a plurality of carboxy groups. From a viewpoint of an HLB value of the carboxy group-containing compound, that influence to an adsorption property to the silicon-germanium surface, the number of carboxy groups contained in the carboxy group-containing compound is preferably 2 or less, and more preferably 1.

The content of carboxy group-containing compound in the etching solution of the present invention is preferably 0.005 mol/L or more and 1.5 mol/L or less, and more preferably 0.05 mol/L or more and 1.0 mol/L or less. A concentration of the compound can be determined by ion chromatography.

Examples of the carboxy group-containing compound include propanoic acid, butanoic acid, pentanoic acid, hexanoic acid, heptanoic acid, octanoic acid, isopropanoic acid, isobutanoic acid, isopentanoic acid, isohexanoic acid, isoheptanoic acid, isooctanoic acid, 2-cyclobutylacetic acid, cyclopentanecarboxylic acid, cyclohexanecarboxylic acid, succinic acid, glutaric acid, adipic acid, pimelic acid, suberic acid, azelaic acid, sebacic acid, tridecanedioic acid, methylsuccinic acid, tetramethylsuccinic acid, benzoic acid, terephthalic acid, gluconic acid, and salts thereof.

Among them, those having a hydrophilic-lipophilic balance (hereinafter referred to as HLB) value of 22.0 to 25.5, such as propanoic acid, butanoic acid, pentanoic acid, hexanoic acid, heptanoic acid, octanoic acid, nonanoic acid, isobutanoic acid, isopentanoic acid, isohexanoic acid, isoheptanoic acid, isooctanoic acid, isononanoic acid, 2-cyclobutylacetic acid, cyclopentanecarboxylic acid, cyclohexanecarboxylic acid, and benzoic acid are more preferable,
butanoic acid, pentanoic acid, hexanoic acid, heptanoic acid, octanoic acid, isobutanoic acid, isopentanoic acid, isohexanoic acid, isoheptanoic acid, isooctanoic acid, 2-cyclobutylacetic acid, cyclopentanecarboxylic acid, cyclohexanecarboxylic acid, and salts thereof, which do not contain an aromatic ring, are more preferable because the selectivity of the etching of silicon with respect to the etching of silicon-germanium can be sufficiently improved, and
those having an HLB value of 23.0 to 25.0, such as butanoic acid, pentanoic acid, hexanoic acid, heptanoic acid, isobutanoic acid, isopentanoic acid, isohexanoic acid, isoheptanoic acid, 2-cyclobutylacetic acid, cyclopentanecarboxylic acid, cyclohexanecarboxylic acid, benzoic acid and salts thereof are even more preferable. In terms of ease of handleability, availability, and the like, butanoic acid, pentanoic acid, hexanoic acid, heptanoic acid, and salts thereof are particularly preferable.

The above HLB value is a value indicating a balance between hydrophilicity and hydrophobicity of a compound, and is a value calculated by a Davies method to be described later. The higher the HLB value, the higher the hydrophilicity of the compound, and the lower the HLB value, the higher the hydrophobicity. When the HLB value of the compound is low, that is, when the hydrophobicity is high, an influence of adsorption of the compound by hydrophobic interaction between a hydrophobic moiety of the compound and the silicon surface is larger than an influence of adsorption of the carboxy group of the carboxy group-containing compound to silicon-germanium, and not only the etching rate of silicon-germanium but also the etching rate of silicon is remarkably reduced. On the other hand, when the HLB value of the carboxy group-containing compound is high, that is, when the hydrophilicity is high, since stability of the carboxy group-containing compound in a solution is high, an adsorption amount of the carboxy group-containing compound not only to the silicon surface but also to the silicon-germanium surface is reduced, or stability in an adsorbed state is reduced, and an effect of preventing the etching of silicon-germanium is reduced. When the HLB value of the carboxy group-containing compound is in a specific range, it is possible to prevent the etching of silicon-germanium by adsorption of the carboxy group while preventing adsorption of the hydrophobic moiety to the silicon surface by the hydrophobic interaction and maintaining the etching rate of silicon, and thus it is possible to improve the selectivity of the etching of silicon with respect to the etching of silicon-germanium. When the above carboxy group-containing compound further contains an amine moiety, since the pKa of the acidic group tends to decrease due to reducing of the pKa of the acidic group by the amine moiety, the carboxy group-containing compound is less likely to be adsorbed to the silicon-germanium surface for the reason described above. Therefore, the above carboxy group-containing compound preferably does not contain the amine moiety.

In the etching solution of the present invention, the carboxy group-containing compound may be present in a form of an ion. That is, the compound includes both a compound in which the carboxy group of the compound is in a form of a non-dissociable carboxy group and a compound in which the carboxy group is in a form of a carboxylate anion. When the carboxy group-containing compound is present in the form of a carboxylate anion, the counter cation (the X⁺) is preferably a non-metal cation. Specifically, various ammonium cations are more preferable, and among them, a quaternary ammonium cation is particularly preferable. More specific examples thereof include a tetramethylammonium cation, an ethyltrimethylammonium cation, a propyltrimethylammonium cation, a butyltrimethylammonium cation, a tetraethylammonium cation, a tetrapropylammonium cation, a tetrabutylammonium cation, a phenyltrimethylammonium cation, and a benzyltrimethylammonium cation.

In the etching solution of the present invention, one type of carboxy group-containing compound may be contained alone, or a plurality of different types of carboxy group-containing compounds may be contained.

The etching solution of the present invention is an alkaline aqueous solution, and water is an essential component as a remainder of a composition of the etching solution. When there is no water, the etching does not proceed. Although a proportion of water depends on types and amounts of other components, in general, the proportion of water is preferably 30% by mass or more and less than 100% by mass, more preferably 50% by mass or more and less than 100% by mass, even more preferably 60% by mass or more and less than 100% by mass, and particularly preferably 75% by mass or more and less than 100% by mass. In addition, an upper limit is not particularly limited as long as the other components can be contained in a necessary amount, and the upper limit is generally 99.5% by mass, and 99% by mass is sufficient.

The silicon etching solution of the present invention may further contain a known component contained in the conventional silicon etching solution made of an alkaline aqueous solution. In this case, a component that reduces the etching rate of silicon or a component that reduces the etching rate of silicon-germanium may be used. Even in a case of blending other components, in the present invention, the selectivity of the etching of silicon with respect to the etching of silicon-germanium can be improved by containing the carboxy group-containing compound as described above. Accordingly, it is possible to reduce an influence on a decrease in selectivity of the etching of silicon with respect to the etching of silicon-germanium due to the blending of the other components. However, since an oxidizing compound capable of oxidizing silicon and silicon-germanium has both an effect of reducing the etching rate of silicon and an effect of increasing the etching rate of silicon-germanium, the oxidizing compound has a large influence on a decrease in selectivity of the etching of silicon with respect to the etching of silicon-germanium, and even when a carboxy group-containing compound is contained, the influence on the decrease in selectivity may not be completely reduced. Therefore, it is preferable not to contain the oxidizing compound capable of oxidizing silicon and silicon-germanium.

Examples of components that may be contained include: one or more water-soluble or water-miscible organic solvents selected from the group consisting of glycols such as ethylene glycol, propylene glycol, and dipropylene glycol, a compound having a plurality of hydroxy groups such as glycerin, alkylene glycol monoalkyl ethers such as ethylene glycol monopropyl ether, ethylene glycol monomethyl ether, diethylene glycol monoethyl ether, propylene glycol monomethyl ether, propylene glycol monoethyl ether, and diethylene glycol n-butyl ether, and ethers having a plurality of ether bonds such as diethylene glycol dimethyl ether, diethylene glycol methyl ethyl ether, and diethylene glycol diethyl ether; one or more quaternary ammonium halogen salts selected from the group consisting of tetramethylammonium chloride, ethyltrimethylammonium iodide, dodecyltrimethylammonium bromide, and decyltrimethylammonium bromide; quaternary ammonium BF₄ salts; corrosion inhibitors such as phenol-based compounds such as hydroquinone, catechol, t-butylcatechol, pyrogallol, gallate ester, p-ethoxyphenol, and o-methoxyphenol; various surfactants; and saccharides.

On the other hand, when silicon is etched in the manufacturing of the semiconductor chip, a silicon dioxide portion (surface) and a silicon nitride portion (surface) are often non-etching target. Therefore, it is preferable that the etching solution of the present invention does not contain a component that promotes etching of silicon dioxide (SiO₂) and silicon nitride (SiN) under an alkaline condition. A typical example of such a component includes a fluoride ion. Other halogen ions such as a chloride ion and a bromide ion may be contained.

The silicon etching solution of the present invention is preferably a uniform solution in which all components blended are dissolved. Further, in the sense of preventing contamination during etching, the number of particles of 200 nm or more is preferably 100 particles/mL or less, and more preferably 50 particles/mL or less. Further, the silicon etching solution of the present invention may contain gases such as hydrogen and oxygen depending on the condition in producing the silicon etching solution.

2. Method for Producing Etching Solution

A method for producing the etching solution of the present invention is not particularly limited, and includes, for example, mixing an alkali compound and a carboxy group-containing compound or a salt thereof with water to have a predetermined concentration and dissolving the components uniformly.

As described above, since the etching solution of the present invention does not contain a metal at a concentration more than an impurity level, it is not preferable to use a metal hydroxide such as NaOH or KOH as the alkali compound.

Therefore, the alkali compound contained in order to make the etching solution of the present invention alkaline is an organic alkali, and is preferably quaternary ammonium hydroxides from a viewpoint of the stability of the silicon etching solution over time. As described above, ammonia may be used as an additional component, but it is preferable not to use ammonia.

As the organic alkali, one containing as few metal impurities and insoluble impurities as possible is preferably used, and a commercially available product can be purified by recrystallization, column purification, ion exchange purification, filtration, or the like as necessary, and used. Depending on a type of the quaternary ammonium hydroxide as the organic alkali, a substance having an extremely high purity is manufactured and sold for use in semiconductor manufacturing, and such product is preferably used. In general, a high-purity quaternary ammonium hydroxide for use in semiconductor manufacturing is sold as a solution such as an aqueous solution. In manufacturing the silicon etching solution of the present invention, this solution may be mixed with water or other blending components as it is.

An amount of the organic alkali necessary for setting the pH of the etching solution to 10.0 or more is generally 0.1 mmol/L or more, although the amount depends on a type and a blending amount of the organic alkali and types and blending amounts of the other components. The larger the amount, the higher the alkaline property (that is, the larger the etching rate of silicon). The amount is more preferably 1 mmol/L or more, and more preferably 10 mmol/L or more, in view of the productivity. The blending amount may be 1200 mmol/L or less, 1000 mmol/L or less, and can often be 800 mmol/L or less to obtain sufficient performance.

When the carboxy group-containing compound is a salt, a non-metal salt is preferable. Specifically, various ammonium salts are more preferable, and among them, a quaternary ammonium salt is particularly preferable. More specific examples thereof include a tetramethylammonium salt, an ethyltrimethylammonium salt, a tetraethylammonium salt, a tetrapropylammonium salt, a tetrabutylammonium salt, a phenyltrimethylammonium salt, and a benzyltrimethylammonium salt.

It is preferable to use high-purity water containing a quite small amount of impurities. An amount of impurities can be evaluated by electrical resistivity, and specifically, the electrical resistivity is preferably 0.1 MΩ·cm or more, more preferably 15 MΩ·cm or more, and particularly preferably 18 MΩ·cm or more. Such water containing a small amount of impurities can be easily manufactured and obtained as ultrapure water for manufacturing a semiconductor. Further, in a case of ultrapure water, impurities that do not influence (have little contribution to) the electrical resistivity are remarkably decreased, and suitability thereof is high.

As described above, various compounds known as components of a chemical solution for manufacturing a semiconductor may be blended as necessary, but the oxidizing compound capable of oxidizing silicon and silicon-germanium is preferably not blended.

The etching solution of the present invention may contain a quaternary ammonium halogen salt such as tetramethylammonium chloride, ethyltrimethylammonium iodide, dodecyltrimethylammonium bromide, and decyltrimethylammonium bromide.

As described above, it is preferable that the etching solution of the present invention does not contain the fluoride ion, and therefore, it is preferable not to contain fluorides such as ammonium fluoride and tetramethylammonium fluoride, even when it is a compound known to be a component of a chemical solution for manufacturing a semiconductor. The same applies to PF₆ salts, BF₄ salts, and the like.

In manufacturing the etching solution of the present invention, it is also preferable to mix and dissolve respective components, and then pass the mixture through a filter of several nm to several tens of nm to remove the particles. If necessary, the filter passing treatment may be performed a plurality of times.

Further, in addition to reducing dissolved oxygen by bubbling with an inert gas such as a high-purity nitrogen gas, various other known treatments can be performed to obtain a necessary physical property in manufacturing the chemical solution for manufacturing a semiconductor.

For mixing and dissolving (and storing), it is preferable to use a container or an apparatus whose inner wall is formed of or coated with a material known for use in the chemical solution for manufacturing a semiconductor, specifically, a material from which a contaminant is hardly eluted into the etching solution, such as polytetrafluoroethylene or a high-purity polypropylene. It is also preferable to clean the container and the apparatus in advance.

3. Method for Manufacturing Semiconductor Device

A method for manufacturing a semiconductor device of the present invention includes a step of bringing the above silicon etching solution into contact with silicon.

The etching solution of the present invention is preferably used as an etching solution in manufacturing a semiconductor device such as a silicon device including a step of etching one or more selected from the group consisting of a single crystal silicon wafer, a single crystal silicon film, a polysilicon film, and an amorphous silicon film. The single crystal silicon film includes a film formed by epitaxial growth.

As the method for manufacturing a semiconductor device of the present invention, a known method for manufacturing a semiconductor device can be used, except for a step of bringing the silicon etching solution of the present invention into contact with a silicon substrate. For example, the method may include known steps used in a method for manufacturing a semiconductor, such as one or more steps selected from a wafer production step, an oxide film forming step, a transistor forming step, a wiring forming step, and a CMP step. Further, it is preferable to include a step of bringing the silicon etching solution of the present invention into contact with silicon-germanium.

A method of bringing the silicon etching solution of the present invention into contact with the silicon substrate is not particularly limited as long as the silicon etching solution and the silicon substrate are in contact with each other, and examples thereof include a method including a substrate holding step of holding the silicon substrate in a horizontal posture and a treatment solution supplying step of supplying the etching solution of the present invention to a main surface of the substrate while rotating the substrate around a vertical rotation axis passing through a central portion of the substrate, or a method including a substrate holding step of holding a plurality of substrates in an upright posture, and a step of immersing the substrates in the etching solution of the present invention stored in a treatment tank in an upright posture.

When the step of bringing the silicon etching solution of the present invention into contact with silicon-germanium is included, the step of bringing the silicon etching solution of the present invention into contact with silicon and the step of bringing the silicon etching solution of the present invention into contact with silicon-germanium may be separate steps, but from a viewpoint of manufacturing efficiency, it is preferable to bring the silicon etching solution into contact with an object containing silicon and silicon-germanium in the same step. The contact in the same step means that a silicon etching solution is simultaneously brought into contact with an object containing silicon and silicon-germanium. For example, by bringing the silicon etching solution into contact with a device structure that uses an oxide film and/or a nitride film as an insulating film and that further has a structure in which a silicon film and a silicon-germanium film are alternately stacked, only silicon can be selectively removed from the device structure. In addition, a nanowire pattern structure for GAA using silicon-germanium or a memory stacked structure such as a 3D NAND can be produced while leaving the oxide film and/or the nitride film as the insulating film.

4. Method for Treating Silicon Wafer or Substrate Having Silicon Film

A method for treating a silicon wafer or a substrate having a silicon film according to the present invention is a method for treating a silicon wafer in which the silicon etching solution of the present invention is brought into contact with a surface of the silicon wafer, or a method for treating a substrate having a silicon film in which the silicon etching solution of the present invention is brought into contact with a surface of the substrate having a silicon film. Here, the silicon film is at least one selected from the group consisting of a single crystal silicon film, a polysilicon film, and an amorphous silicon film.

Examples of the method for treating a silicon wafer in which the silicon etching solution of the present invention is brought into contact with the surface of the silicon wafer include a method including a step of etching a single crystal silicon film by supplying the silicon etching solution of the present invention when etching a silicon wafer, particularly various silicon composite semiconductor devices containing silicon-germanium.

Examples of the method for treating a substrate having a silicon film in which the silicon etching solution of the present invention is brought into contact with the surface of the substrate having a silicon film include a method including a substrate holding step of holding the substrate having a silicon film in a horizontal posture and a treatment solution supplying step of supplying the etching solution of the present invention to a main surface of the substrate while rotating the substrate around a vertical rotation axis passing through a central portion of the substrate.

Examples of another method for treating a substrate having a silicon film include a method including a substrate holding step of holding a plurality of substrates in an upright posture, and a step of immersing the substrates in the etching solution of the present invention stored in a treatment tank in an upright posture.

5. Etching Treatment

The silicon etching solution of the present invention can be suitably used for manufacturing a semiconductor device including a step of etching a single crystal silicon film by supplying an etching solution when etching a silicon wafer, particularly various silicon composite semiconductor devices containing silicon-germanium.

A temperature of the silicon etching solution at a time of etching using the silicon etching solution of the present invention may be appropriately determined in a range of 20° C. to 95° C. in consideration of a desired etching rate, a shape and a surface state of silicon after etching, the productivity, and the like, and is preferably set to a range of 35° C. to 90° C.

At the time of etching using the silicon etching solution of the present invention, it is preferable to perform the etching while performing deaeration or bubbling with an inert gas under vacuum or under a reduced pressure. Such an operation can prevent or reduce an increase in dissolved oxygen during the etching.

At the time of etching using the silicon etching solution of the present invention, an object to be etched may be simply immersed in and contact with an etching solution, and an electrochemical etching method of applying a constant potential to the object to be etched can also be used.

Examples of a target object to be etched in the present invention include single crystal silicon, polysilicon, and amorphous silicon containing a silicon-germanium film, which are non-target objects not to be etched and need to be left in the target object. In addition to the silicon-germanium film, a silicon oxide film, a silicon nitride film, various metal films, or the like may be included as the non-target objects. Examples thereof include a structure in which silicon and silicon-germanium are alternately stacked, a structure in which the silicon-germanium film, the silicon oxide film, or the silicon nitride film is formed on single crystal silicon, a structure in which silicon, polysilicon, or silicon-germanium is further formed thereon, and a structure in which a pattern is formed using these films.

### EXAMPLES

Hereinafter, the present invention is described in more detail with reference to Examples, but the present invention is not limited to these Examples.

Experimental methods/evaluation methods in Examples and Comparative Examples are as follows.

### (Method for Preparing Etching Solution)

As an organic alkaline compound, a tetramethylammonium hydroxide (TMAH) aqueous solution (2.73 mol/L) or tetrabutylammonium hydroxide (TBAH) (1.54 mol/L) aqueous solution was diluted and mixed with ultrapure water to make a uniform chemical solution, then various additives were added thereto to prepare a composition of each etching solution according to each of Examples and Comparative Examples shown in Table 1, and the etching solution was heated at a temperature during an etching treatment for a predetermined time. At this time, in order to remove dissolved oxygen in the solution, nitrogen bubbling was performed at a supply rate of 0.2 L/min for the last 30 minutes.

### (Method for Measuring pH of Etching Solution)

Measurement was performed under a temperature condition of 25° C. using a tabletop pH meter F-73 manufactured by Horiba, Ltd., and a pH electrode 9632-10D for a strong alkaline sample manufactured by Horiba, Ltd.

### (pKa of Carboxy Group-containing Compound)

Values of the following general documents were referenced. pKa 1 represents an acid dissociation constant of first dissociation, pKa 2 represents an acid dissociation constant of second dissociation, and pKa 3 represents an acid dissociation constant of third dissociation.
Reference Document 1: Everett et al. [Proceedings of the Royal Society of London, Series A: Mathematical, Physical and Engineering Sciences, 1952, vol. 215, p. 403, 409]
Reference Document 2: Edwards, H. G. M.; Smith, D. N. [Journal of Molecular Structure, 1990, vol. 238, #1, p. 27-41]
Reference Document 3: Sari, Hayati; Covington, Arthur K. [Journal of Chemical and Engineering Data, 2005, vol. 50, #5, p. 1620-1623]
Reference Document 4: EP2708533A1

### (HLB Value of Carboxy Group-containing Compound)

An HLB value was calculated using the following Formula 1 (Davies method). The number of hydrophilic groups used is 19.1 for a Na salt of a carboxy group (—COO⁻Na⁺), and the number of hydrophobic groups used is −0.475 for a methylene group (—CH₂—), a methyl group (—CH₃), and a methine group (═CH—). Since it is considered that an etching solution of this example is alkaline and almost all the carboxy groups are ionized, a value of the Na salt is used.

HLB value=7+total value of number of hydrophilic groups+total value of number of lipophilic groups (1)

(Silicon Etching Rate and Etching Selectivity Ratio between Si and SiGe)

A silicon etching solution (100 mL) heated to a predetermined solution temperature was prepared, and a substrate (silicon (100 plane) film, manufactured by Global Net Corp.) obtained by epitaxially growing silicon (Si) on a silicon-germanium (SiGe) substrate having a size of 2 cm×1 cm was immersed therein for 15 seconds. During the etching, the solution was stirred at 1200 rpm, and nitrogen bubbling was continued at 0.2 L/min. The etching rate (R′₁₀₀) of the silicon (100 plane) film was obtained by measuring a film thickness of each substrate before and after etching with a spectroscopic ellipsometer, obtaining an etching amount of the silicon film based on a difference in film thickness before and after the treatment, and dividing the etching amount by the etching time.

Similarly, an etching rate (R_{SiGe}) at the temperature was calculated by immersing, for 10 minutes, a substrate (a silicon-germanium film, manufactured by Global Net Corp.) obtained by epitaxially growing silicon-germanium on a silicon substrate having a size of 2 cm×1 cm.

Based on the measurement results, an etching selectivity ratio between the silicon (100 plane) film and the silicon-germanium film (R′₁₀₀/R_{SiGe}) was obtained.

A lower limit of measurement of the change in film thickness by the spectroscopic ellipsometer used is 0.01 nm. Therefore, a lower limit of an etching rate of the silicon-germanium film that can be determined by the above method is 0.001 nm/min.

### Reference Example

Using a 0.26 mol/L TMAH aqueous solution, silicon and silicon-germanium etching rates were evaluated. The results are shown in Table 1.

### Example 1

Using an aqueous solution having a TMAH concentration of 0.26 mol/L and a hexanoic acid concentration of 0.09 mol/L, the etching rates of silicon and silicon-germanium were evaluated under conditions of a heating time of 1 hour and a heating time of 24 hours during preparation of the aqueous solution. The pKa of hexanoic acid is 4.84 (Reference Document 1), and the HLB value of hexanoic acid is 23.7. The result is shown in Table 1. In this experimental example, the etching selectivity ratio (R′₁₀₀/R_{SiGe}) between the silicon (100 plane) film and the silicon-germanium film was 705 when the heating time was 1 hour and 911 when the heating time was 24 hours, which was extremely excellent under both conditions. In addition, the pH of the aqueous solution when the heating time was 1 hour was 13.26, and the pH of the aqueous solution when the heating time was 24 hours was 13.23, which were hardly changed.

### Examples 2 and 3

An etching solution containing various additives shown in Table 1 instead of hexanoic acid was prepared and evaluated under the condition of a heating time of 1 hour. The results are shown in Table 1.

### Comparative Examples 1 to 4

An etching solution containing various additives shown in Table 1 instead of hexanoic acid was prepared and evaluated under the condition of a heating time of 1 hour. The results are shown in Table 1.

In Comparative Example 4, which is an experimental example in which ethanesulfonic acid (pKa: −1.7 (Reference Document 2)) having the smallest pKa was added, no improvement is observed as compared with a case where no additive is added (Reference Example). In addition, in Comparative Examples 1 to 3, which are experimental examples in which phthalic acid (pKa 1: 3.1, pKa 2: 5.08 (Reference Document 3)), and phosphoric acid (pKa 1: 2.12, pKa 2: 7.2, pKa 3: 12.36 (Reference Document 4)) having a plurality of pKa, and hexylphosphonic acid are added, respectively, improvement is observed as compared with a case where no additive is added, but an improvement effect is small as compared with Examples 1 to 4 in which hexanoic acid, butanoic acid, and heptanoic acid are added.

### Example 4

An etching solution containing TBAH, i.e., an organic alkali having 16 carbon atoms, instead of TMAH was prepared, and was evaluated under the condition of a heating time of 1 hour. Concentrations and an evaluation result are shown in Table 1. In this experimental example, both the etching rates of silicon and silicon-germanium are lower than those in Example 1 in which TMAH is used as the alkaline compound.

### Comparative Example 5

An etching solution containing an additive shown in Table 1 instead of hexanoic acid was prepared, and was evaluated under the conditions of a heating time of 1 hour and a heating time of 24 hours. The results are shown in Table 1. Maltose, that is, an additive used in this experimental example, is a disaccharide having a reducing property. When the heating time was 1 hour, the etching selectivity ratio (R′₁₀₀/R_{SiGe}) between the silicon (100 plane) film and the silicon-germanium film was excellent, but when the heating time was 24 hours, the etching selectivity ratio deteriorated significantly. In addition, the pH of the aqueous solution when the heating time was 1 hour was 13.00, and the pH of the aqueous solution when the heating time was 24 hours was 10.42, which were significantly reduced.

TABLE 1

| | Etching solution composition | | | | | | | | | | | | | Etching |
|---|---|---|---|---|---|---|---|---|---|---|---|---|---|---|
| | | | Additive | | | | | | | | Etch- | | | selec- |
| | Organic alkali | | | | Davies | | | | Etching | Heat- | ing | Etching rate | | tivity |
| | | Concen- | | Concen- | method | | | | temper- | ing | solu- | (nm/min) | | ratio |
| | | tration | | tration | HLB | pKa (at 25° C.) | | | ature | time | tion | Si | | Si/ |
| | Type | (mol/L) | Type | (mol/L) | value | pKa 1 | pKa 2 | pKa 3 | (° C.) | (hr) | pH | (100) | SiGe | SiGe |
| Reference | TMAH | 0.26 | Not added | — | N.D. | N.D. | N.D. | N.D. | 43 | 1 | 13.41 | 84 | 1.3 | 63 |
| Example | | | | | | | | | | | | | | |
| Example | TMAH | 0.26 | Hexanoic | 0.09 | 23.7 | 4.84 | N.D. | N.D. | 43 | 1 | 13.26 | 61 | 0.09 | 705 |
| 1 | | | acid | | | | | | | 24 | 13.23 | 77 | 0.09 | 911 |
| Example | TMAH | 0.26 | Butanoic | 0.11 | 24.7 | 4.82 | N.D. | N.D. | 43 | 1 | N.D. | 85 | 0.5 | 180 |
| 2 | | | acid | | | | | | | | | | | |
| Example | TMAH | 0.26 | Heptanoic | 0.08 | 23.3 | 4.89 | N.D. | N.D. | 43 | 1 | N.D. | 71 | 0.2 | 318 |
| 3 | | | acid | | | | | | | | | | | |
| Compar- | TMAH | 0.26 | Phthalic | 0.06 | 42.4 | 3.1 | 5.08 | N.D. | 43 | 1 | N.D. | 102 | 1.0 | 102 |
| ative | | | acid | | | | | | | | | | | |
| Example | | | | | | | | | | | | | | |
| 1 | | | | | | | | | | | | | | |
| Compar- | TMAH | 0.26 | Phos- | 0.10 | N.D. | 2.12 | 7.2 | 12.36 | 43 | 1 | N.D. | 83 | 0.8 | 104 |
| ative | | | phoric | | | | | | | | | | | |
| Example | | | acid | | | | | | | | | | | |
| 2 | | | | | | | | | | | | | | |
| Compar- | TMAH | 0.26 | Hexyl- | 0.06 | N.D. | N.D. | N.D. | N.D. | 43 | 1 | N.D. | 99 | 1.0 | 104 |
| ative | | | phos- | | | | | | | | | | | |
| Example | | | phonic | | | | | | | | | | | |
| 3 | | | acid | | | | | | | | | | | |
| Compar- | TMAH | 0.26 | Ethane- | 0.09 | N.D. | −1.7 | N.D. | N.D. | 43 | 1 | N.D. | 60 | 1.2 | 52 |
| ative | | | sulfonic | | | | | | | | | | | |
| Example | | | acid | | | | | | | | | | | |
| 4 | | | | | | | | | | | | | | |
| Example | TBAH | 0.26 | Hexanoic | 0.09 | 23.7 | 4.84 | N.D. | N.D. | 43 | 1 | N.D. | 4 | 0.03 | 128 |
| 4 | | | acid | | | | | | | | | | | |
| Compar- | TMAH | 0.26 | Maltose | 0.09 | N.D. | N.D. | N.D. | N.D. | 43 | 1 | 13.00 | 155 | 0.07 | 2214 |
| ative | | | | | | | | | | | | | | |
| Example | | | | | | | | | | 24 | 10.42 | 20 | 0.2 | 100 |
| 5 | | | | | | | | | | | | | | |

1. A silicon etching solution comprising:
an organic alkali;
water; and
a compound having at least one carboxy group and having all pKa of 3.5 or more and 13 or less, or a salt thereof.

2. The silicon etching solution according to claim 1, wherein the compound has an HLB value of 22.0 or more and 25.5 or less.

3. The silicon etching solution according to claim 1, wherein the compound is a compound not containing an amine moiety.

4. The silicon etching solution according to claim 1, wherein the compound is one or more compounds selected from the group consisting of propanoic acid, butanoic acid, pentanoic acid, hexanoic acid, heptanoic acid, octanoic acid, isopropanoic acid, isobutanoic acid, isopentanoic acid, isohexanoic acid, isoheptanoic acid, isooctanoic acid, 2-cyclobutylacetic acid, cyclopentanecarboxylic acid, cyclohexanecarboxylic acid, succinic acid, glutaric acid, adipic acid, pimelic acid, suberic acid, azelaic acid, sebacic acid, tridecanedioic acid, methylsuccinic acid, tetramethylsuccinic acid, benzoic acid, terephthalic acid, and gluconic acid.

5. The silicon etching solution according to claim 1, wherein the organic alkali is a quaternary ammonium hydroxide.

6. The silicon etching solution according to claim 5, wherein the quaternary ammonium hydroxide is a quaternary ammonium hydroxide having 8 or less carbon atoms.

7. A method for treating a silicon wafer or a substrate, comprising:
selectively etching silicon with respect to silicon-germanium in a silicon wafer including a silicon-germanium film, or selectively etching at least one selected from the group consisting of a single crystal silicon film, a polysilicon film, and an amorphous silicon film with respect to silicon-germanium in a substrate including a silicon-germanium film, by using the silicon etching solution according to claim 1.

8. A method for manufacturing a silicon device, comprising:
a step of selectively etching silicon with respect to silicon-germanium in a silicon wafer including a silicon-germanium film, or a step of selectively etching at least one selected from the group consisting of a single crystal silicon film, a polysilicon film, and an amorphous silicon film with respect to silicon-germanium in a substrate including a silicon-germanium film, by using the silicon etching solution according to claim 1.
